(19) United States
(12) Patent Application Publication
(10) Pub. No.: US 2012/0241311 A1
(43) Pub. Date: Sep. 27, 2012

(54) SPUTTERING DEVICE AND SPUTTERING METHOD

(75) Inventor: Satoshi KATO, Oita (JP)

(73) Assignee: Kabushiki Kaisha Toshiba, Tokyo (JP)

(21) Appl. No.: 13/354,670

(22) Filed: Jan. 20, 2012

(30) Foreign Application Priority Data
Mar. 24, 2011 (JP) 2011-066668

(51) Int. Cl. C23C 14/35

(52) U.S. Cl. 204/192.12; 204/298.16

(57) ABSTRACT

According to the embodiment, a sputtering device and a sputtering method includes: a target of which a bottom surface is arranged so as to be opposed to a wafer substrate; a magnetic field forming portion which is arranged to be opposed to an upper surface of the target, and includes a magnet forming a magnetic field; a mechanism which changes a distance from a center point on a surface of the target opposed to the wafer substrate to a predetermined reference point of the magnetic field forming portion, while making the magnetic field forming portion go around the center point, with maintaining a spacing between the target and the magnetic field forming portion; and a wafer retaining portion which is capable of arranging the wafer substrate at a predetermined position.

### CROSS-REFERENCE TO RELATED APPLICATIONS

This application is based upon and claims the benefit of priority of Japanese Patent Application No. 2011-066668, filed on Mar. 24, 2011, the entire contents of which are incorporated herein by reference.

### FIELD

Embodiments described herein relate generally to a sputtering device and a sputtering method.

### BACKGROUND

Conventionally, as a device for forming a thin film on a surface of a wafer substrate, a sputtering device has been known. In the sputtering device mentioned above, the thin film is formed by bringing an ion of an inert gas into collision with a target material for forming the thin film within the device, and depositing an atom of the material which is discharged from the target by collision energy on a surface of the wafer substrate.

Further, as one kind of the sputtering device, there is a magnetron type sputtering device in which a film forming speed is enhanced by setting a magnet at a position which is opposed to the wafer substrate via the target, and promoting the collision of the ion into the target by the magnet.

In the magnetron type sputtering device mentioned above, since an intensity of a magnetic field formed by the magnet is lacking in uniformity, an erosion speed of the target which is eroded by the collision of the ion is different in the portion of the target.

Further, it is necessary for the target to be replaced even in a state in which a usable portion remains, in the case that an amount of erosion of the locally eroded portion reaches a fixed amount. In accordance with this, in the magnetron type sputtering device, it is necessary to improve utilization efficiency of the target.

### BRIEF DESCRIPTION OF THE DRAWINGS

FIG. 1 is a schematic view illustrating a sputtering device in accordance with a first embodiment;

FIG. 2 is a view illustrating a shape, an arrangement and a motion of members which are driven by each of drive units of the sputtering device in accordance with the first embodiment;

FIG. 3A and FIG. 3B are views illustrating a moving range of a magnet portion with respect to a bottom surface of a target in accordance with the first embodiment;

FIG. 4 is a schematic view illustrating a sputtering device in accordance with a second embodiment;

FIG. 5 is a view illustrating a motion of members which are driven by each of drive units of the sputtering device in accordance with the second embodiment; and

FIG. 6 is a view illustrating a moving locus of a magnet portion in accordance with a third embodiment.

### DETAILED DESCRIPTION

In general, according to one embodiment, a sputtering device and a sputtering method includes: a target of which a bottom surface is arranged so as to be opposed to a wafer substrate; a magnetic field forming portion which is arranged to be opposed to an upper surface of the target, and includes a magnet forming a magnetic field; a mechanism which changes a distance from a center point on a surface of the target opposed to the wafer substrate to a predetermined reference point of the magnetic field forming portion, while making the magnetic field forming portion go around the center point, with maintaining a spacing between the target and the magnetic field forming portion; and a wafer retaining portion which is capable of arranging the wafer substrate at a predetermined position.

Exemplary embodiments of a sputtering device and a sputtering method will be explained below in detail with reference to the accompanying drawings. The present invention is not limited to the following embodiments.

### First Embodiment

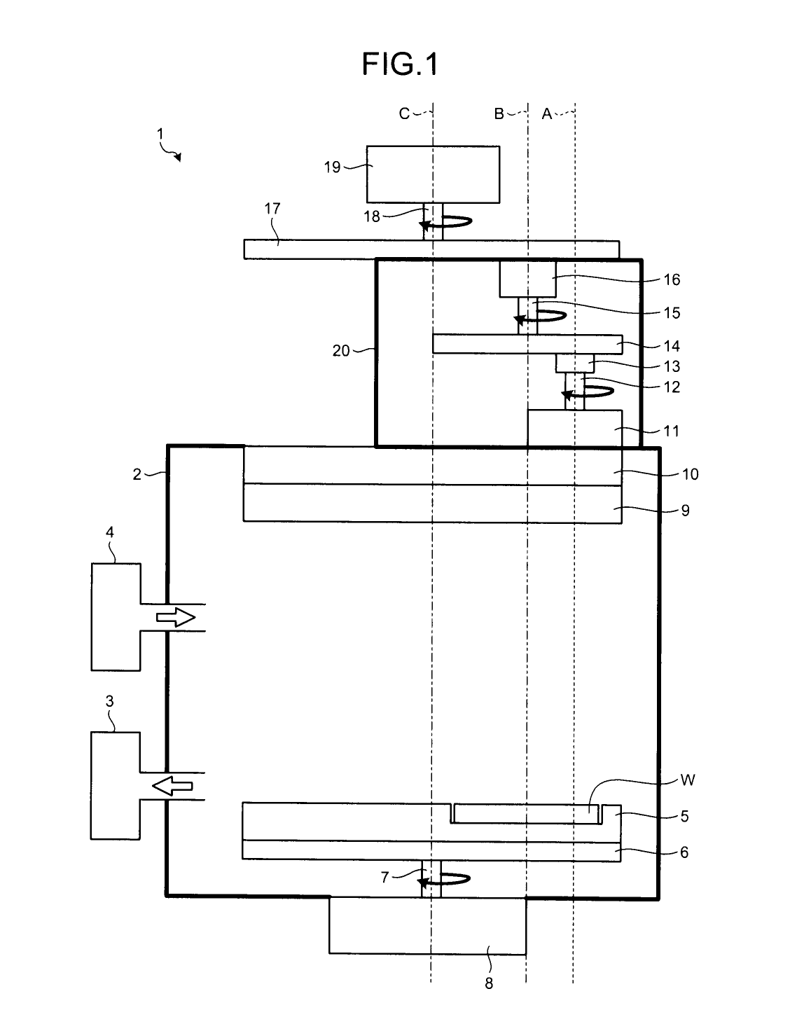

As illustrated in FIG. 1, a sputtering device 1 is provided with a processing chamber 2, a vacuum control portion 3, and a gas feed portion 4. The processing chamber 2 is a processing chamber which carries out a sputtering process with respect to a wafer substrate W, for example, a silicone wafer.

The vacuum control portion 3 is a vacuum pump which depressurizes the processing chamber 2 by sucking an air from an inside of the processing chamber 2. The gas feed portion 4 is a processing portion which introduces an inert gas (for example, an argon gas) for generating a plasma to the inside of the processing chamber 2.

Further, the sputtering device 1 is provided with a wafer retaining portion (hereinafter, described as “pedestal 6”) which retains the wafer substrate W to be processed in the inside of the processing chamber 2. The pedestal 6 retains a shield 5 in which the wafer substrate W is set at a predetermined position. Further, the sputtering device 1 is provided with a substrate drive unit 8. The substrate drive unit 8 rotates the pedestal 6 by rotating around a rotating axis C.

Further, the sputtering device 1 is provided with a target 9 which can be arranged such that a bottom surface is opposed in parallel to an upper surface of the wafer substrate W, and a back plate 10 which retains the target 9 in the inside of the processing chamber 2.

The target is formed as a disc shape, and is a member which becomes material to form a thin film formed in the surface of the wafer substrate W. Further, the back plate 10 is a discoid member which has the same diameter as the target 9. In this case, the diameters and the shapes of the target 9 and the back plate 10 are not limited to them.

Here, a description will be briefly given of a film forming procedure of the thin film by the sputtering device 1 mentioned above. The sputtering device 1 first of all depressurizes the inside of the processing chamber 2 to a predetermined atmospheric pressure by the vacuum control portion 3. Subsequently, the sputtering device 1 introduces the inert gas into the processing chamber 2 by the gas feed portion 4.

Subsequently, the sputtering device 1 forms the inert gas as plasma by applying a predetermined voltage between the target 9 and the pedestal 6, and brings the plasma ion into collision with a bottom surface of the target 9. An atom of the target 9 is bumped out of the target 9 on the basis of a collision of the ion mentioned above. Further, the sputtering device 1 forms a thin film which is constructed by the atom of the target 9 on a surface of the wafer substrate W by depositing the atom bumped out of the target 9 on the surface of the wafer substrate W.

Further, the sputtering device 1 is provided with a magnetron device 20 at a position which is opposed to the target 9 via the back plate 10. The magnetron device 20 mentioned above is a device which forms a magnetic field on a bottom surface of the target 9. Further, in the sputtering device 1, a film forming speed is enhanced by forming the magnetic field by the magnetron device 20 so as to enhance a density of the ion colliding with the target 9.

The magnetron device 20 is provided with a magnetic field forming portion (hereinafter, described as “magnet portion 11”) to which one or more magnet is fixed, a magnet drive unit 13, a unit support plate 14, and a support plate drive unit 16.

The magnet portion 11 is a discoid member, is arranged at a position which is opposed to the target 9 via the back plate 10, and forms a magnetic field on the bottom surface of the target 9. The magnet portion 11 is connected to a magnet drive unit 13 by a rotating shaft 12 which is provided in a rising manner in the center of the upper surface. In this case, a diameter and a shape of the magnet portion 11 are not limited to them.

The magnet drive unit 13 rotates the rotating shaft 12 around a axis A corresponding to a first axis, thereby making the magnet portion 11 rotate on the axis A as a rotation axis, while keeping the bottom surface of the magnet portion 11 and the bottom surface of the target 9 in parallel. The magnet drive unit 13 mentioned above is supported by the unit support plate 14.

The unit support plate 14 is a discoid support member, and supports the magnet drive unit 13 which is attached to a predetermined position of a lower surface. The unit support plate 14 is connected to the support plate drive unit 16 by the rotating shaft 15 which is provided in a rising manner in the center of the upper surface.

The support plate drive unit 16 rotates the rotating shaft 15 around a axis B corresponding to a second axis, thereby making the unit support plate 14 rotate on the axis B as a rotation axis, while keeping the bottom surface of the unit support plate 14 and the bottom surface of the target 9 in parallel.

Further, the sputtering device 1 is provided with a device support plate 17 which supports the magnetron device 20, and a device drive unit 19 which drives the device support plate 17. The device support plate 17 is a discoid support member, and supports the support plate drive unit 16 which is attached to a predetermined position in a lower surface. The device support plate 17 is connected to the device drive unit 19 by a rotating shaft 18 which is provided in a rising manner in the center of an upper surface.

The device drive unit 19 rotates the rotating shaft 18 around a axis C corresponding to a third axis, thereby making the device support plate 17 rotate on the axis C as a rotation axis, while keeping a bottom surface of the device support plate 17 and the bottom surface of the target 9 in parallel.

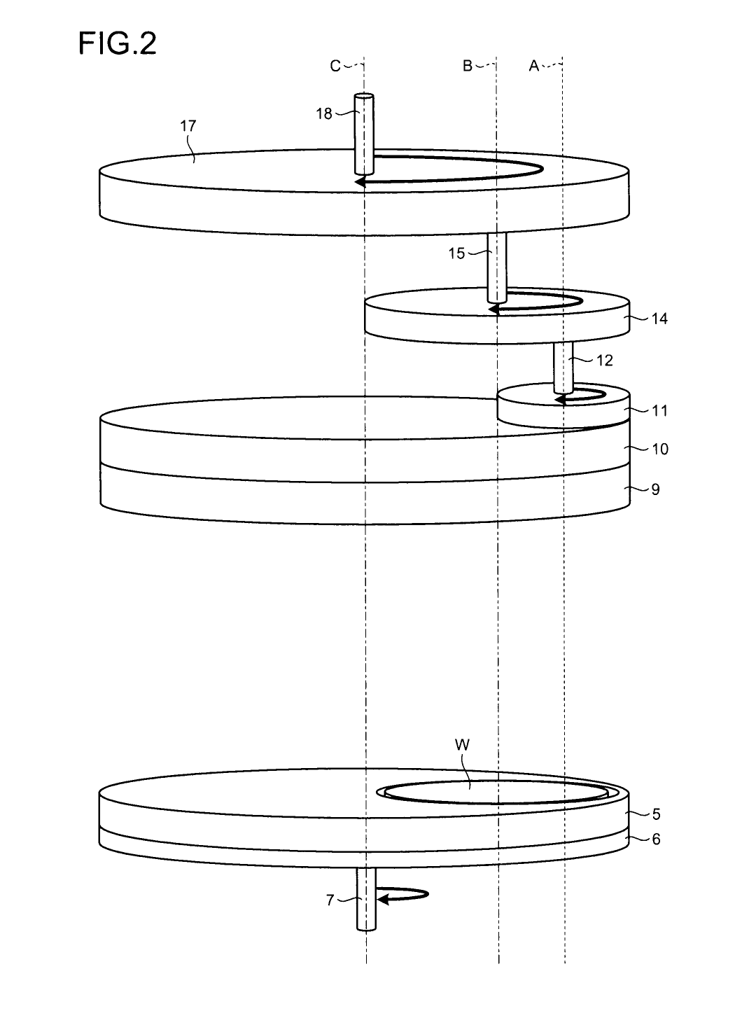

Next, a description will be given of a shape, an arrangement and a motion of members which are driven by each of the drive units of the sputtering device 1 with reference to FIG. 2. FIG. 2 is a view illustrating the shape, the arrangement and the motion of the members which are driven by each of the drive units of the sputtering device 1 in accordance with the first embodiment. In this case, an illustration of each of the drive units is omitted.

As illustrated in FIG. 2, in the sputtering device 1, the pedestal 6, the shield 5, the target 9, the back plate 10 and the device support plate 17 have the same diameter. In this case, the diameter is no more than one example, and the diameter of each of the portions can be changed.

Further, in the sputtering device 1, the pedestal 6, the shield 5, the target 9, the back plate 10 and the device support plate 17 are arranged such that the centers of the upper and lower surfaces are positioned on the axis C. Further, the rotating shaft 7 rotating the pedestal 6 and the rotating shaft 18 rotating the device support plate 17 are arranged in such a manner as to rotate by using the axis C as the axis of rotation.

The shield 5 is provided with a fitting hole which can fit the discoid wafer substrate W between the center of the upper surface and an outer periphery, and retains the wafer substrate W within the fitting hole mentioned above.

The unit support plate 14 is formed in such a manner that a diameter becomes equal to a radius of the target 9. In this case, the diameter mentioned above is no more than one example. Further, the unit support plate 14 is arranged at a position which passes through a middle point between the center of the bottom surface in the target 9 and the outer periphery of the target 9, and rotates by using the axis B which is in parallel to the axis C as a rotation axis.

A diameter of the magnet portion 11 is equal to a radius of the unit support plate 14. In this case, the diameter mentioned above is no more than one example. Further, the magnet portion 11 is arranged at a position which passes through a middle point between the center of the bottom surface in the unit support plate 14 and the outer periphery of the unit support plate 14, and rotates by using the axis A which is in parallel to the axis B as a rotation axis.

Further, in the sputtering device 1, the magnet portion 11, the unit support plate 14, the device support plate 17 and the pedestal 6 are simultaneously rotated. At this time, in the sputtering device 1, the unit support plate 14 is rotated at a rotating speed which is slower than a rotating speed of the magnet portion 11, and the device support plate 17 is rotated at a rotating speed which is slower than the rotating speed of the unit support plate 14.

In other words, in the sputtering device 1, the magnet portion 11 goes around the axis B while rotating on the axis A as a rotation axis while maintaining a distance from the target 9, and goes around the axis C, by simultaneously rotating the magnet portion 11, the unit support plate 14, the device support plate 17 and the pedestal 6.

As mentioned above, in the sputtering device 1, the magnet portion 11 is moved above the target 9 as mentioned above, by a mechanism which includes the rotating shaft 12 connected to the magnet portion 11, in an interlocking manner, the magnet drive unit 13, the unit support plate 14, the rotating shaft 15, the support plate drive unit 16, the device support plate 17, the rotating shaft 18 and the device drive unit 19.

In accordance with this, in the sputtering device 1, it is possible to change a distance from a center point in the surface which is opposed to the wafer substrate W of the target 9 to a predetermined reference point in the magnet portion 11 (for example, a center point in the lower surface in the magnet portion 11). Accordingly, the sputtering device 1 can move the magnet portion 11 in such a manner as to cover all the regions which are faced to the upper surface of the back plate 10, while maintaining the distance from the target 9.

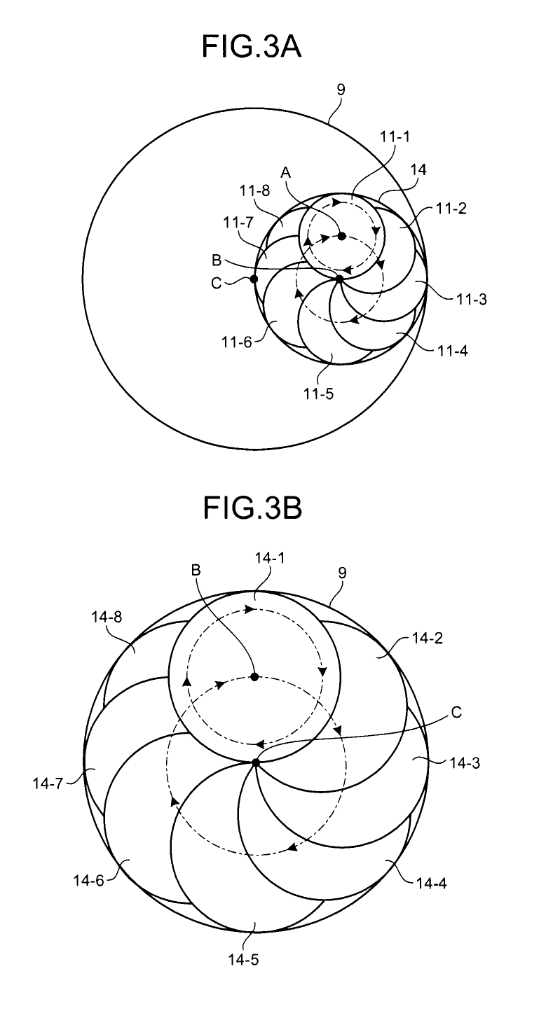

In this case, a description will be given of a moving range of the magnet portion 11 with respect to the bottom surface of the target 9 with reference to FIG. 3A and FIG. 3B. FIG. 3A and FIG. 3B are views illustrating the moving range of the magnet portion 11 with respect to the bottom surface of the target 9 in accordance with the first embodiment.

In this case, FIG. 3A illustrates the moving range of the magnet portion 11 which moves by the support plate drive unit 16, and FIG. 3B illustrates the moving range of the magnet portion 11 which moves by the device drive unit 19. Further, FIG. 3A illustrates the moving range of the magnet portion 11 in the case that the axis B is fixed in the light of simplification of the description.

As illustrated in FIG. 3A, in the sputtering device 1, the unit support plate 14 is rotated by means of the support plate drive unit 16 on the axis B as a rotation axis, while making the magnet portion 11 rotate on the axis A as a rotation axis (refer to a dotted arrow in FIG. 3A).

As a result, the magnet portion 11 goes around the axis B so as to return to a position 11-1 while moving to positions 11-1, 11-2, 11-3, 11-4, 11-5, 11-6, 11-7 and 11-8 in accordance with this order.

In accordance with this, in the sputtering device 1, it is possible to move the magnet portion 11 above the target 9 in such a manner as to cover all the regions which laps over the unit support plate 14 in the bottom surface of the target 9.

Further, in the sputtering device 1, as illustrated in FIG. 3B, the device support plate 17 is rotated by means of the device drive unit 19 on the axis C as a rotation axis, while making the unit support plate 14 rotate on the axis B as a rotation axis (refer to a single dotted chain arrow in FIG. 3B).

As a result, the unit support plate 14 goes around the axis C so as to return to a position 14-1 while moving to positions 14-1, 14-2, 14-3, 14-4, 14-5, 14-6, 14-7 and 14-8 in accordance with this order.

As mentioned above, in the sputtering device 1, the unit support plate 14 is moved above the target 9 in such a manner as to cover all the regions of the bottom surface in the target 9. Further, as mentioned above, the magnet portion 11 moves above the target 9 in such a manner as to cover all the regions which lap over the unit support plate 14 in the bottom surface of the target 9.

Accordingly, in the sputtering device 1, it is possible to move the magnet portion 11 above the target 9 in such a manner as to cover a whole of the bottom surface of the target 9, and it is possible to move over all the regions in the bottom surface of the target 9 in a region with which the ion collides at a high density.

In accordance with this, the sputtering device 1 can improve utilization efficiency of the target 9 by uniformly bringing the ion into collision with a hole of the bottom surface of the target 9 so as to uniformly erode a whole of the bottom surface.

Further, in the sputtering device 1, even in the case that the atom which is discharged out of the target 9 is reattached to the bottom surface of the target 9, a period in which the ion collides with the portion at which the atom is reattached at a high density comes over in a fixed cycle. In accordance with this, in the sputtering device 1, since the atom which is reattached to the bottom surface of the target 9 is periodically removed, it is possible to prevent a particle from being generated on a formed thin film.

Returning to the description of FIG. 2, a description of an arrangement and a motion of the members which are driven by each of the drive units is carried on. In the sputtering device 1, the pedestal 6 is structured such that the wafer substrate W can be arranged, so that the center of the wafer substrate W and the axis B corresponding to the second axis coincide.

Specifically, the sputtering device 1 controls the rotation of the pedestal 6 and the device support plate 17 in such a manner that the rotating speed of the pedestal 6 by the substrate drive unit 8 is equal to the rotating speed of the device support plate 17 by the device drive unit 19.

Further, the sputtering device 1 controls the rotation of the pedestal 6 and the device support plate 17 in such a manner that the center point of the surface of the wafer substrate W is always positioned on an extension of the axis B which comes to the rotating axis of the rotating shaft 15 rotating the unit support plate 14.

In other words, the sputtering device 1 maintains a state in which the wafer substrate W and the unit support plate 14 areas of which are equal in a plan view are always opposed. Further, as mentioned above, the sputtering device 1 moves the magnet portion 11 above the target 9 in such a manner as to cover all the regions which lap over the unit support plate 14 in the bottom surface of the target 9.

In accordance with this, in the sputtering device 1, it is possible to uniformly deposit the atoms of the target 9 to the surface of the wafer substrate W from the region which faces to the wafer substrate W in the bottom surface of the target 9, and it is possible to form a thin film having a uniform film thickness.

As mentioned above, the sputtering device 1 in accordance with the first embodiment is provided with the target 9 of which the bottom surface is arranged so as to be opposed to the upper surface of the wafer substrate W, the magnet portion 11 which is arranged to be opposed to the upper surface of the target 9 and includes the magnet forming the magnetic field, and the mechanism which changes the distance from the center point in the surface opposed to the wafer substrate W of the target 9 to the predetermined reference point in the magnet portion 11, while maintaining the spacing between the target 9 and the magnet portion 11.

In accordance with the structure mentioned above, the sputtering device 1 can move the magnet portion 11 above the target 9 in such a manner as to cover a whole of the bottom surface of the target 9. In accordance with this, the sputtering device 1 can improve utilization efficiency of the target 9 by uniformly bringing the ion into collision with a whole of the bottom surface of the target 9 so as to uniformly erode a whole of the bottom surface of the target 9.

Further, the sputtering device 1 changes the distance from the center point in the surface which is opposed to the wafer substrate W of the target 9 to the predetermined reference point in the magnet portion 11, while making the magnet portion 11 go around the center point in the surface which is opposed to the wafer substrate W of the target 9.

In accordance with this, since the sputtering device 1 can periodically bring the ion having a high density into collision with each of the positions of the bottom surface in the target 9, it is possible to prevent the particle from being generated in the thin film which is formed by periodically removing the atom reattached to the bottom surface of the target 9.

Further, the sputtering device 1 is provided with a first rotating mechanism (the magnet drive unit 13) which rotates the magnet portion 11 along the upper surface of the target 9 by using the axis A which comes to a first axis as a rotation axis, and a second rotating mechanism (the support plate drive unit 16) which rotates the first axis along the upper surface of the target 9 by using the axis B which comes to a second axis as a rotation axis.

Further, the sputtering device 1 is provided with a third rotating mechanism (the device drive unit 19) which rotates the second axis along the upper surface of the target 9 by using the axis C which comes to a third axis being in parallel to the second axis while passing through the center point in the surface opposed to the wafer substrate W of the target 9 as a rotation axis.

In accordance with the structure mentioned above, the sputtering device 1 can move the magnet portion 11 to an optional position which is opposed to the bottom surface of the target 9 on the basis of a combination of the rotation and the revolution of the magnet portion 11.

Therefore, in accordance with the sputtering device 1, since it is possible to exclude a region in which a frequency of the ion collision is steadily low, from the bottom surface of the target 9, it is possible to improve the utilization efficiency of the target 9 by uniformly eroding a whole of the bottom surface of the target 9.

### Second Embodiment

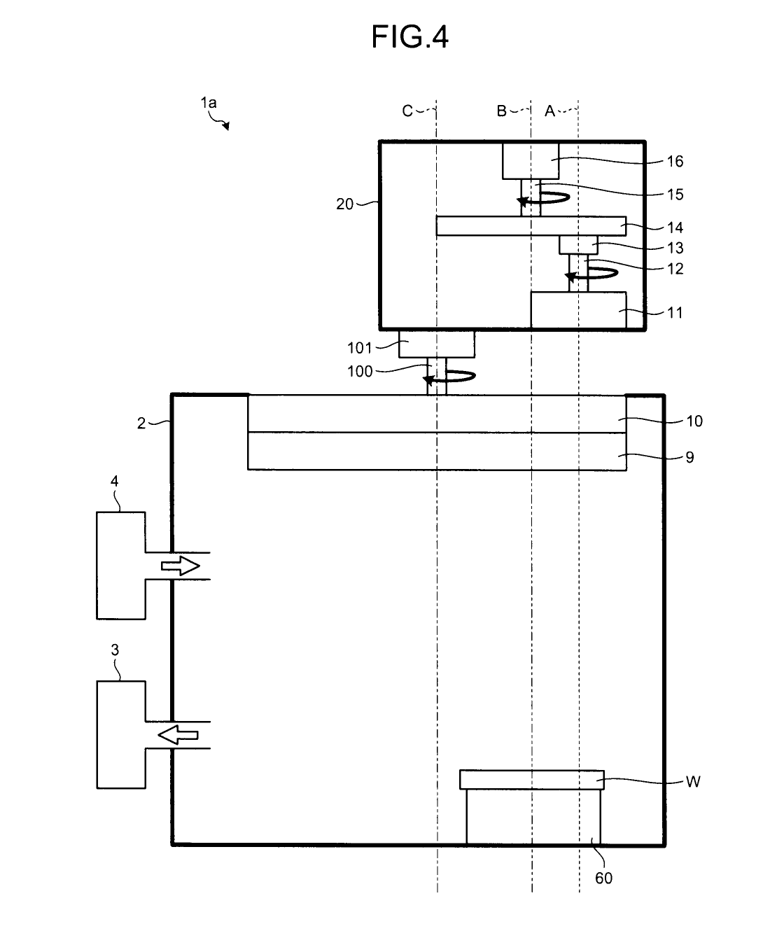

Next, a description will be given of a sputtering device 1a in accordance with a second embodiment with reference to FIG. 4. FIG. 4 is a schematic view illustrating the sputtering device 1a in accordance with the second embodiment. In this case, in FIG. 4, the same reference numerals are attached to the same constituent elements as the sputtering device 1 illustrated in FIG. 1.

As illustrated in FIG. 4, the sputtering device 1a is different from the sputtering device 1 illustrated in FIG. 1 in a point that the magnetron device 20 is fixed, a point that a target drive unit 101 is provided, and a point that a pedestal 60 is fixed.

In other words, the shapes and the arrangements of the wafer substrate W, the target 9, the back plate 10, the magnet portion 11, the rotating shaft 12, the magnet drive unit 13, the unit support plate 14, the rotating shaft 15 and the support plate drive unit 16 in the sputtering device 1a are the same as those illustrated in FIG. 1. Further, the relative positions of the axes A, B and C illustrated in FIG. 4 are the same as those illustrated in FIG. 1.

The target drive unit 101 of the sputtering device la mentioned above rotates the back plate 10 and the target 9 by using the axis C as a rotation axis, by driving a rotating shaft 100 which is provided in a rising manner in the center of the upper surface of the back plate 10.

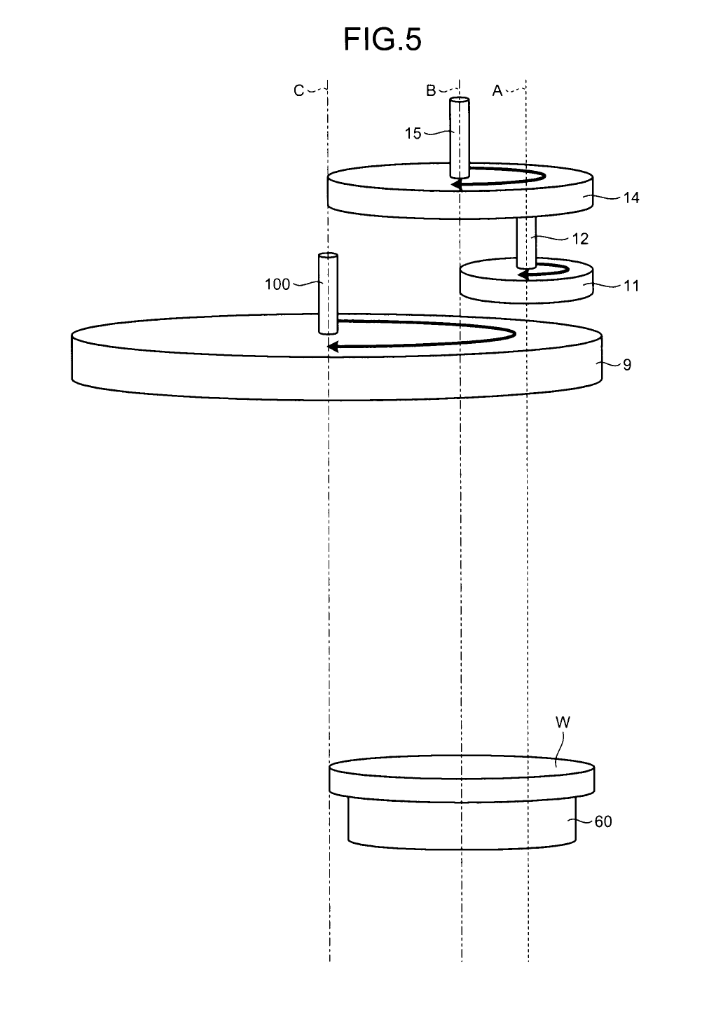

In this case, a description will be given of a motion of members which are driven by each of the drive units of the sputtering device 1a with reference to FIG. 5. FIG. 5 is a view illustrating a motion of the members which are driven by each of the drive units of the sputtering device 1a in accordance with the second embodiment.

As illustrated in FIG. 5, in the sputtering device 1a, the magnet portion 11 goes around the axis B which passes through the center point of the surface of the wafer substrate W while rotating on the axis A as a rotation axis. In accordance with this, the magnet portion 11 moves above the target 9 in such a manner as to cover all the regions which lap over the unit support plate 14 in the bottom surface of the target 9.

Further, if the rotating shaft 100 is rotationally driven by the target drive unit 101, the target 9 rotates on the axis C as a rotation axis while shifting the region which laps over the unit support plate 14.

In accordance with the motion mentioned above, the sputtering device 1a can change a distance from the center point in the surface which is opposed to the wafer substrate W of the target 9 to a predetermined reference point in the magnet portion 11, while maintaining the spacing between the target 9 and the magnet portion 11.

As mentioned above, the sputtering device 1a in accordance with the second embodiment is provided with a first rotating mechanism (the magnet drive unit 13) which rotates the magnet portion 11 along the upper surface of the target 9 by using the axis A which comes to a first axis as a rotation axis, and a second rotating mechanism (the support plate drive unit 16) which rotates the first axis along the upper surface of the target 9 by using the axis B which comes to a second axis as a rotation axis.

Further, the sputtering device 1a is provided with a third rotating mechanism (the target drive unit 101) which rotates the target 9 by using the axis C which comes to a third axis being in parallel to the second axis while passing through the center point in the surface opposed to the wafer substrate W of the target 9 as a rotation axis.

In accordance with the structure mentioned above, the sputtering device 1a can move the magnet portion 11 in such a manner as to cover the whole region of the bottom surface of the target 9 on the basis of a combination of the rotation and the revolution of the magnet portion 11, and the rotation of the target 9.

Therefore, the sputtering device 1a can improve utilization efficiency of the target 9 by uniformly eroding a whole of the bottom surface of the target 9, in the same manner as the sputtering device 1 illustrated in FIG. 1. Further, the sputtering device 1a can periodically removes the atom which is reattached to the bottom surface of the target 9, in the same manner as the sputtering device 1 illustrated in FIG. 1.

In this case, in the embodiment mentioned above, the description is given of the case that the area of the moving region of the magnet portion 11 is equal to the bottom area of the target 9, however, the area of the moving region of the magnet portion 11 may be made wider than the bottom area of the target 9.

In the case mentioned above, the magnet drive unit 13 is attached in such a manner that the rotating shaft 12 which is provided in a rising manner on the upper surface of the magnet 11 comes to a position which is closer to the outer periphery than the center in the bottom surface of the unit support plate 14.

Further, in the case of the sputtering device 1 in accordance with the first embodiment, the support plate drive unit 16 may be attached in such a manner that the rotating shaft 15 which is provided in a rising manner on the upper surface of the unit support plate 14 comes to a position which is closer to the outer periphery than the center in the bottom surface of the device support plate 17.

In accordance with this, in the sputtering devices 1 and 1a, it is possible to move the magnet portion 11 above the target 9 in such a manner as to securely cover a peripheral edge portion in the bottom surface of the target 9.

In this case, in the embodiments mentioned above, the description is given of the case that orbits of the rotation and the revolution of the magnet portion 11 are all constructed by a circular orbit, however, the orbits of the rotation and the revolution of the magnet portion 11 may be set to the other optional orbits than the circular orbit.

Further, in the embodiments mentioned above, the description is given of the case that the magnet portion 11 goes around the center point in the surface which is opposed to the wafer substrate W of the target 9, however, the magnet portion 11 may be reciprocated above the target 9.

### Third Embodiment

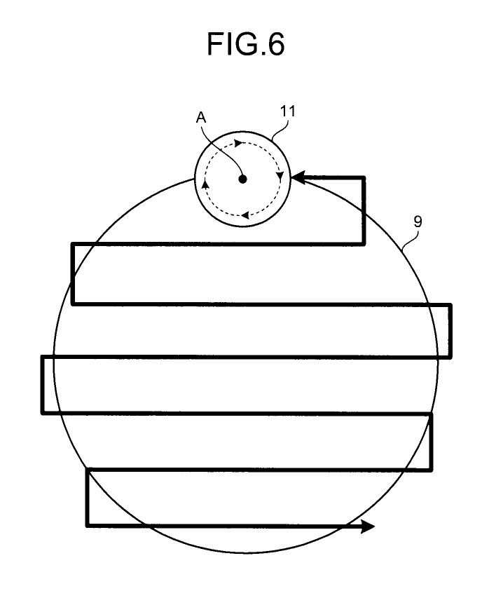

Next, a description will be given of a sputtering device in accordance with a third embodiment in which the magnet portion 11 is reciprocated above the target 9 with reference to FIG. 6. FIG. 6 is a view illustrating a moving locus of the magnet portion 11 which is moved by the sputtering device in accordance with the third embodiment.

As illustrated in FIG. 6, the sputtering device in accordance with the third embodiment reciprocates the magnet portion 11 by meandering so as to scan above the target 9 while keeping the distance between the bottom surface of the target 9 and the magnet portion 11 constant, while making the magnet portion 11 rotate on the axis A as a rotation axis.

In this case, the sputtering device is provided with a mechanism for moving the magnet portion 11 in a first direction in parallel to the bottom surface of the target 9, and a mechanism for moving the magnet portion 11 in a second direction which is orthogonal to the first direction in parallel to the bottom surface of the target 9.

In accordance with the structure mentioned above, since the sputtering device can move the magnet portion 11 at an optional position which is opposed to the bottom surface of the target 9, it is possible to improve utilization efficiency of the target 9 by uniformly eroding a whole of the bottom surface of the target 9.

In this case, in the first to third embodiment mentioned above, the description is given of the case of always changing the relative position between the target 9 and the unit support plate 14 during the formation of the thin film, however, the relative position between the target 9 and the unit support plate 14 may be fixed for a predetermined period and be changed periodically.

For example, the relative position between the target 9 and the unit support plate 14 may be fixed for a predetermined period during an execution of a predetermined film forming process, and the relative position between the target 9 and the unit support plate 14 may be changed in the case that the process is switched.

Further, the relative position between the target 9 and the unit support plate 14 may be fixed until a previously determined time has passed, and the relative position between the target 9 and the unit support plate 14 may be changed in the case that the previously determined time has passed. In accordance with the structure mentioned above, it is possible to uniformly erode a whole of the bottom surface of the target 9 by repeating the change of the relative position between the target 9 and the unit support plate 14.

Further, in the first to third embodiments, the description is given of the case that the magnet portion 11 is rotated, however, it is possible to uniformly erode a whole of the bottom surface of the target 9 even by changing the relative position between the target 9 and the unit support plate 14 without making the magnet portion 11 rotate.

Further, the sputtering device may be structured such as to make the unit support plate 14 go around the axis C as a rotation axis while making the target 9 rotate on the axis C as a rotation axis, on the basis of a combination of the technique which is described in the first embodiment, and the technique which is described in the second embodiment. Even in accordance with the structure mentioned above, it is possible to uniformly erode a whole of the bottom surface of the target 9.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A sputtering device comprising:
a target of which a bottom surface is arranged so as to be opposed to a wafer substrate;
a magnetic field forming portion which is arranged to be opposed to an upper surface of the target, and includes a magnet forming a magnetic field;
a mechanism which changes a distance from a center point on a surface of the target opposed to the wafer substrate to a predetermined reference point of the magnetic field forming portion, while making the magnetic field forming portion go around the center point, with maintaining a spacing between the target and the magnetic field forming portion; and
a wafer retaining portion which is capable of arranging the wafer substrate at a predetermined position.

2. The sputtering device according to claim 1,
wherein the mechanism includes:
a first rotating mechanism which rotates the magnetic field forming portion along an upper surface of the target by using a first axis as a rotation axis;
a second rotating mechanism which rotates the first axis along the upper surface of the target by using a second axis as a rotation axis; and
a third rotating mechanism which rotates the second axis along the upper surface of the target by using a third axis which passes through the center point and is in parallel to the second axis as a rotation axis.

3. The sputtering device according to claim 1,
wherein the mechanism includes:
a first rotating mechanism which rotates the magnetic field forming portion along an upper surface of the target by using a first axis as a rotation axis;
a second rotating mechanism which rotates the first axis along the upper surface of the target by using a second axis as a rotation axis; and
a third rotating mechanism which rotates the target by using a third axis which passes through the center point and is in parallel to the second axis as a rotation axis.

4. The sputtering device according to claim 2, wherein the mechanism comprises a fourth rotating mechanism which rotates the target by using the third axis as a rotation axis.

5. The sputtering device according to claim 2, wherein the wafer retaining portion is capable of arranging the wafer substrate in such a manner that a center of the wafer substrate coincides with the second axis.

6. The sputtering device according to claim 3, wherein the wafer retaining portion is capable of arranging the wafer substrate in such a manner that a center of the wafer substrate coincides with the second axis.

7. The sputtering device according to claim 4, wherein the wafer retaining portion is capable of arranging the wafer substrate in such a manner that a center of the wafer substrate coincides with the second axis.

8. The sputtering device according to claim 2, wherein the mechanism rotates the first axis by using the second axis as a rotation axis at a speed which is slower than a rotating speed of the magnetic field forming portion using the first axis as a rotation axis, and rotates the second axis by using the third axis as a rotation axis at a rotating speed which is slower than a rotating speed of the first axis.

9. The sputtering device according to claim 3, wherein the mechanism rotates the first axis by using the second axis as a rotation axis at a speed which is slower than a rotating speed of the magnetic field forming portion using the first axis as a rotation axis, and rotates the second axis by using the third axis as a rotation axis at a rotating speed which is slower than a rotating speed of the first axis.

10. The sputtering device according to claim 4, wherein the mechanism rotates the first axis by using the second axis as a rotation axis at a speed which is slower than a rotating speed of the magnetic field forming portion using the first axis as a rotation axis, and rotates the second axis by using the third axis as a rotation axis at a rotating speed which is slower than a rotating speed of the first axis.

11. The sputtering device according to claim 2, wherein the mechanism repeats a motion for fixing a relative position between the target and the second axis, during an execution of a predetermined film forming process, and a motion for changing the relative position between the target and the second axis in the case that the film forming process is finished.

12. The sputtering device according to claim 3, wherein the mechanism repeats a motion for fixing a relative position between the target and the second axis, during an execution of a predetermined film forming process, and a motion for changing the relative position between the target and the second axis in the case that the film forming process is finished.

13. The sputtering device according to claim 4, wherein the mechanism repeats a motion for fixing a relative position between the target and the second axis, during an execution of a predetermined film forming process, and a motion for changing the relative position between the target and the second axis in the case that the film forming process is finished.

14. The sputtering device according to claim 2, wherein the mechanism repeats a motion for fixing a relative position between the target and the second axis, until a predetermined time has passed, and a motion for changing the relative position between the target and the second axis in the case that the predetermined time has passed.

15. The sputtering device according to claim 3, wherein the mechanism repeats a motion for fixing a relative position between the target and the second axis, until a predetermined time has passed, and a motion for changing the relative position between the target and the second axis in the case that the predetermined time has passed.

16. The sputtering device according to claim 4, wherein the mechanism repeats a motion for fixing a relative position between the target and the second axis, until a predetermined time has passed, and a motion for changing the relative position between the target and the second axis in the case that the predetermined time has passed.

17. The sputtering device according to claim 1,
wherein the mechanism includes:
a rotating mechanism which rotates the magnetic field forming portion along an upper surface of the target by using a first axis as a rotation axis;
a first reciprocating mechanism which reciprocates the magnetic field forming portion in a first direction in parallel to the bottom surface of the target; and
a second reciprocating mechanism which reciprocates the magnetic field forming portion in a second direction which is orthogonal to the first direction in parallel to the bottom surface of the target.

18. The sputtering device according to claim 17, wherein the first reciprocating mechanism and the second reciprocating mechanism make the magnetic field forming portion meander so as to scan above the target while keeping a distance between the bottom surface of the target and the magnetic field forming portion constant.

19. The sputtering device according to claim 1, wherein the magnetic field forming portion has a plurality of the magnets.

20. A sputtering method comprising:
arranging a bottom surface of a target so as to be opposed to a wafer substrate;
arranging a magnetic field forming portion which includes a magnet forming a magnetic field so as to be opposed to an upper surface of the target; and
carrying out a film forming process by changing a distance from a center point on a surface of the target opposed to the wafer substrate to a predetermined reference point of the magnetic field forming portion, while making the magnetic field forming portion go around the center point, with maintaining a spacing between the target and the magnetic field forming portion.
